(19) United States
(12) Patent Application Publication
(10) Pub. No.: US 2026/0090442 A1
(43) Pub. Date: Mar. 26, 2026

(54) SEMICONDUCTOR DEVICE

(71) Applicants: KABUSHIKI KAISHA TOSHIBA, Kawasaki-shi (JP); Toshiba Electronic Devices & Storage Corporation, Kawasaki-shi (JP)

(72) Inventor: Kyo Tanabiki, Himeji Hyogo (JP)

(21) Appl. No.: 19/314,336

(22) Filed: Aug. 29, 2025

(30) Foreign Application Priority Data
Sep. 20, 2024 (JP) 2024-163639

(51) Int. Cl. H01L 23/00; H01L 23/31

(52) U.S. Cl. CPC H10W 72/60; H10W 72/621; H10W 72/631; H10W 72/646; H10W 74/111; H10W 90/767

(57) ABSTRACT

According to one embodiment, a semiconductor device includes the following structure. A semiconductor chip is provided between first and second conductors. A first connector is provided between the semiconductor chip and the second conductor. The second conductor includes a first plate, a second plate, and a third plate, which are continuously provided. The first plate extends in a first direction along a main surface of the semiconductor chip and is connected to the semiconductor chip via the first connector. The second plate extends from the first plate in a direction intersecting the first direction, and includes a first surface continuous from a surface on which the first connector is provided, and includes a groove provided on the first surface. The third plate extends from the second plate in the first direction.

### CROSS-REFERENCE TO RELATED APPLICATION

This application is based upon and claims the benefit of priority from Japanese Patent Application No. 2024-163639, filed Sep. 20, 2024, the entire contents of which are incorporated herein by reference.

### FIELD Embodiments described herein relate generally to a semiconductor device.

### BACKGROUND

A semiconductor device including a semiconductor package on which a semiconductor chip is mounted is known.

### BRIEF DESCRIPTION OF DRAWINGS

FIG. 1 is a perspective view illustrating an outer shape of a semiconductor device according to a first embodiment.

FIG. 2 is a plan view illustrating a configuration of the semiconductor device according to the first embodiment.

FIG. 3 is a cross-sectional view illustrating the configuration of the semiconductor device according to the first embodiment.

FIG. 4 is a cross-sectional view illustrating a connection structure between a semiconductor chip and a conductor according to the first embodiment.

FIG. 5 is a cross-sectional view illustrating a connection structure between a semiconductor chip and a conductor according to a first modification of the first embodiment.

FIG. 6 is a cross-sectional view illustrating a connection structure between a semiconductor chip and a conductor according to a second modification of the first embodiment.

FIG. 7 is a cross-sectional view illustrating a connection structure between a semiconductor chip and a conductor according to a comparative example.

FIG. 8 is a plan view illustrating a configuration of a semiconductor device according to a second embodiment.

FIG. 9 is a cross-sectional view illustrating the configuration of the semiconductor device according to the second embodiment.

FIG. 10 is a cross-sectional view illustrating a connection structure between a semiconductor chip and a conductor according to the second embodiment.

FIG. 11 is a plan view illustrating a configuration of a semiconductor device according to a third embodiment.

FIG. 12 is a cross-sectional view illustrating the configuration of the semiconductor device according to the third embodiment.

FIG. 13 is a cross-sectional view illustrating a connection structure between a semiconductor chip and a conductor according to the third embodiment.

FIG. 14 is a plan view illustrating a configuration of a semiconductor device according to a first modification of the third embodiment.

FIG. 15 is a plan view illustrating a configuration of a semiconductor device according to a second modification of the third embodiment.

FIG. 16 is a plan view illustrating a configuration of a semiconductor device according to a fourth embodiment.

FIG. 17 is a cross-sectional view illustrating the configuration of the semiconductor device according to the fourth embodiment.

FIG. 18 is a cross-sectional view illustrating a configuration of a semiconductor device according to a first modification of the fourth embodiment.

FIG. 19 is a cross-sectional view illustrating a configuration of a semiconductor device according to a second modification of the fourth embodiment.

### DETAILED DESCRIPTION

In general, according to one embodiment, a semiconductor device includes a first conductor, a second conductor, a semiconductor chip and a first connector. The semiconductor chip is provided between the first conductor and the second conductor. The first connector is provided between the semiconductor chip and the second conductor. The second conductor includes a first plate, a second plate, and a third plate, which are continuously provided. The first plate extends in a first direction along a main surface of the semiconductor chip and is connected to the semiconductor chip via the first connector. The second plate extends from the first plate in a direction intersecting the first direction, and includes a first surface continuous from a surface on which the first connector is provided, and includes a groove provided on the first surface. The third plate extends from the second plate in the first direction.

Hereinafter, embodiments will be described with reference to the drawings. In the following description, components having the same function and configuration are denoted by the same reference numeral. The following embodiments exemplify an apparatus and a method for embodying the technical idea of the embodiments, and do not specify the material, shape, structure, arrangement and the like of the components as follows.

### 1. First Embodiment

A semiconductor device according to a first embodiment is described.

### 1.1 Configuration of Semiconductor Device

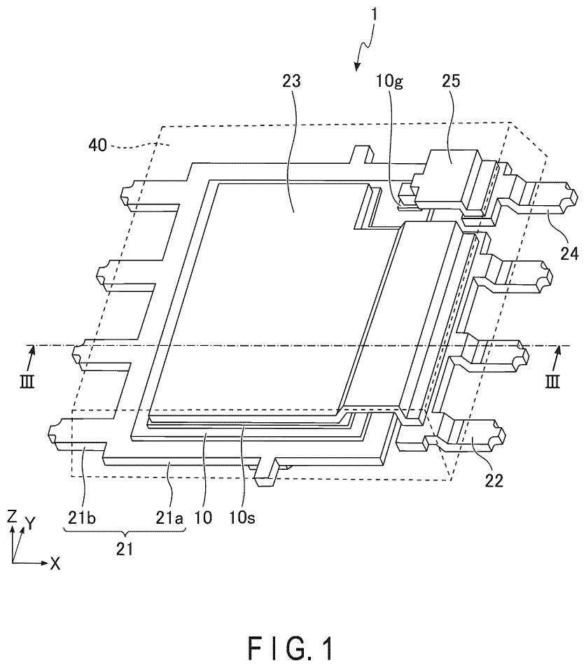

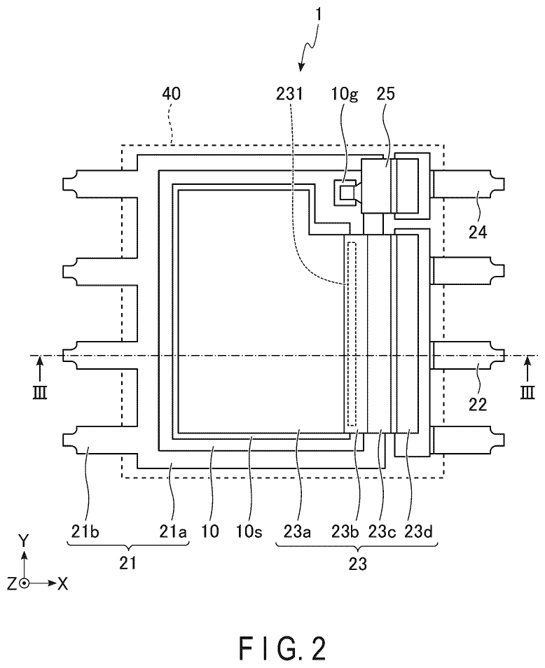

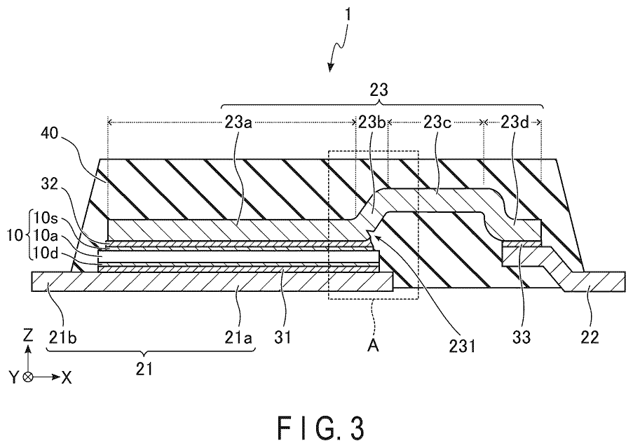

FIG. 1 is a perspective view illustrating an outer shape of the semiconductor device according to the first embodiment. FIG. 2 is a plan view illustrating a configuration of the semiconductor device according to the first embodiment. FIG. 3 is a cross-sectional view of the semiconductor device taken along line III-III in FIGS. 1 and 2. FIGS. 1 and 2 are diagrams as seen through a resin covering the semiconductor device. In the following description, in FIGS. 1 to 3, a direction of an arrow in an X direction is simply referred to as an X direction, and a direction opposite to the arrow is referred to as a −X direction. As for a Y direction and a Z direction, similarly, directions of arrows in the Y direction and the Z direction are simply referred to as the Y direction and the Z direction, respectively, and directions opposite to the arrows are referred to as a −Y direction and a −Z direction. The Z direction is referred to as upward, and the −Z direction is referred to as downward in some cases.

As illustrated in FIGS. 1 to 3, a semiconductor device 1 includes a semiconductor chip (or a semiconductor element) 10, conductors 21 to 25, connectors (or connection members, connection materials, joining members) 31 to 33, and a resin 40. The semiconductor chip 10 is provided between the conductor 21 and the conductor 23.

Furthermore, the conductor 23 is provided on the conductor 22.

The semiconductor chip 10 includes, for example, a metal oxide semiconductor field effect transistor (MOSFET) or an insulated gate bipolar transistor (IGBT). Here, a case where the semiconductor chip 10 is the MOSFET is described.

The semiconductor chip 10 includes, for example, a source electrode 10s, a drain electrode 10d, a gate electrode 10g, and a semiconductor layer 10a. The semiconductor layer 10a is provided between the source electrode 10s and the drain electrode 10d. Note that, the source electrode 10s and the drain electrode 10d may be interchanged as necessary.

The semiconductor chip 10 includes a first main surface (or a lower surface) and a second main surface (or an upper surface). The first main surface is a surface provided on the-Z direction side, and the second main surface is a surface provided on the Z direction side. The drain electrode 10d is provided on the first main surface of the semiconductor chip 10. The source electrode 10s and the gate electrode 10g are provided on the second main surface of the semiconductor chip 10.

The conductor 21 is a part of a lead frame on which the semiconductor chip 10 is placed. The conductor 21 includes a base 21a and a plurality of protrusions 21b.

The conductor 21 mainly contains, for example, a conductive material such as copper.

The base 21a is a region on which the semiconductor chip 10 is placed. The semiconductor chip 10 is provided on the base 21a of the conductor 21. The conductor 21 is arranged so as to face the drain electrode 10d of the semiconductor chip 10, and is electrically connected to the drain electrode 10d.

The plurality of protrusions 21b is regions extending from the base 21a in the −X direction. The plurality of protrusions 21b functions as lead terminals (for example, drain terminals) connectable to the outside.

The connector 31 is provided between the semiconductor chip 10 and the conductor 21. The connector 31 fixes the semiconductor chip 10 to the base 21a of the conductor 21. Therefore, the drain electrode 10d of the semiconductor chip 10 is electrically connected to the conductor 21 via the connector 31. The connector 31 mainly contains a conductive material such as solder or silver.

A plurality of conductors 22 is provided so as to be separated from the conductor 21 in the X direction and is arrayed in the Y direction. The conductor 22 is a part of the lead frame. The conductor 22 functions as a lead terminal (for example, a source terminal) connectable to the outside. The conductor 22 mainly contains, for example, a conductive material such as copper.

The conductor 23 is provided on the source electrode 10s of the semiconductor chip 10 and the conductor 22. The conductor 23 is arranged so as to face the source electrode 10s of the semiconductor chip 10 and the conductor 22, and is electrically connected to the source electrode 10s and the conductor 22. The conductor 23 mainly contains, for example, a conductive material such as copper.

The conductor 23 includes a portion (or a first plate) 23a, a portion (or a second plate) 23b, a portion (or a third plate) 23c, and a portion (or a fourth plate) 23d. The portion 23a is a region facing the semiconductor chip 10 and electrically connected to the semiconductor chip 10. The portion 23a is a region extending along the second surface of the semiconductor chip 10, that is, a region extending linearly in the X direction. The portion 23d is a region facing the conductor 22 and electrically connected to the conductor 22. The portions 23b and 23c are regions between the portion 23a and the portion 23d, and are regions that do not face neither the semiconductor chip 10 nor the conductor 22. The portion 23b is a region continuous from the portion 23a and extending from the portion 23a in a direction intersecting the X direction.

More specifically, the portion 23b is a region continuous from the portion 23a and extending linearly from the portion 23a in an oblique direction with respect to the X direction and the Z direction. The portion 23c is a region continuous from the portion 23b and extending linearly from the portion 23b in the X direction. Furthermore, the portion 23d is a region continuous from the portion 23c, bent from the portion 23c in the-Z direction, and further extending along an upper surface of the conductor 22, that is, extending linearly in the X direction. With such a structure, by increasing a distance between the portion 23c of the conductor 23 and the conductor 21, an insulation property between the conductor 23 and the conductor 21 can be enhanced.

A connector 32 is provided between the portion 23a of the conductor 23 and the semiconductor chip 10. The connector 32 fixes the conductor 23 to the semiconductor chip 10. Therefore, the source electrode 10s of the semiconductor chip 10 is electrically connected to the conductor 23 via the connector 32. The connector 32 mainly contains a conductive material such as solder or silver.

The portion 23b of the conductor 23 includes a first surface and a second surface on a side opposite to the first surface. The first surface is a surface in the X direction (or in the-Z direction) of the portion 23b, and the second surface is a surface in the-X direction (or in the Z direction) of the portion 23b.

A groove (or a recess) 231 is provided on the first surface of the portion 23b in the conductor 23. The groove 231 will be described later in detail.

The connector 33 is provided between the portion 23d of the conductor 23 and the conductor 22. The connector 33 fixes the conductor 23 to the conductor 22. Therefore, the conductor 22 is electrically connected to the conductor 23 via the connector 33. The connector 33 mainly contains a conductive material such as solder or silver.

As illustrated in FIGS. 1 and 2, the conductor 24 is provided so as to be separated from the conductor 22 in the Y direction. The conductor 24 is a part of the lead frame. The conductor 24 functions as a lead terminal (for example, a gate terminal) connectable to the outside. The conductor 24 mainly contains, for example, a conductive material such as copper.

The conductor 25 is provided on the gate electrode 10g of the semiconductor chip 10 and the conductor 24. The conductor 25 is arranged so as to face the gate electrode 10g of the semiconductor chip 10 and the conductor 24, and is electrically connected to the gate electrode 10g and the conductor 24. The conductor 25 mainly contains, for example, a conductive material such as copper.

Furthermore, the resin 40 covers the semiconductor chip 10, a part of the conductor 21, a part of the conductor 22, the conductor 23, a part of the conductor 24, and the conductor 25. The resin 40 resin-seals the semiconductor chip 10 and the conductors 21 to 25.

### 1.2 Configuration of Groove of Conductor

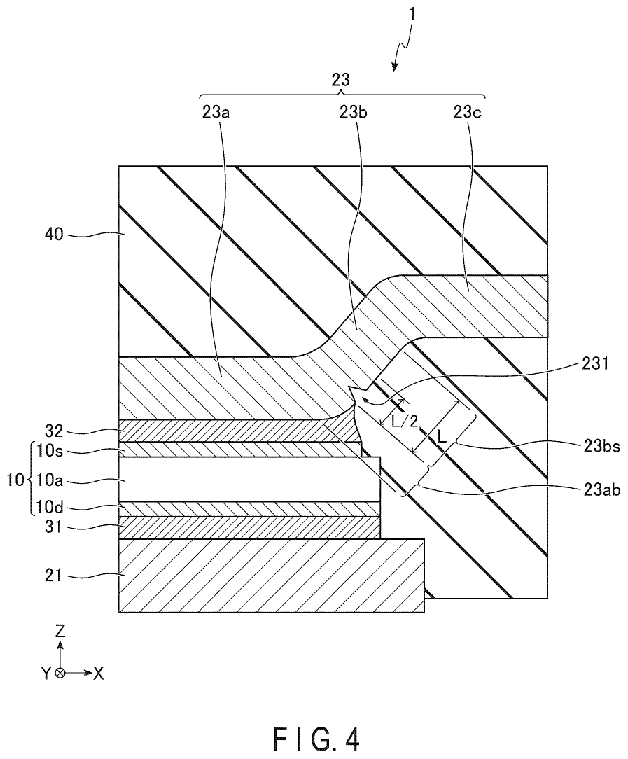

Next, a connection structure between the semiconductor chip 10 and the conductor 23, and the groove 231 provided in the portion 23b of the conductor 23 will be described in detail with reference to FIG. 4. FIG. 4 is an enlarged view of a portion A in FIG. 3, and is a cross-sectional view illustrating the connection structure between the source electrode 10s of the semiconductor chip 10 and the conductor 23.

As described above, the source electrode 10s of the semiconductor chip 10 is connected to the portion 23a of the conductor 23 via the connector 32. The conductor 23 includes the portion 23a extending linearly in the X direction, the portion 23b extending linearly from the portion 23a in the direction intersecting the X direction, for example, in the oblique direction with respect to the X direction and the Z direction, and the portion 23c extending linearly from the portion 23b in the X direction.

As illustrated in FIG. 4, a curved portion (or a bent portion) 23ab is provided between the portion 23a and the portion 23b of the conductor 23 (or a boundary therebetween). The curved portion 23ab is a region (or a surface) provided in a curved shape between the portion 23a and the portion 23b. In the portion 23b, a linear portion 23bs is provided continuously from the curved portion 23ab. The linear portion 23bs is a linearly extending region (or surface) provided in the portion 23b.

The groove 231 is provided on the first surface of the portion 23b of the conductor 23, that is, on a surface in the X direction (or in the −Z direction) of the portion 23b. In other words, the groove 231 is provided on the surface of the conductor 23 continuous from the surface on which the connector 32 is provided.

The groove 231 is a portion recessed inside the conductor 23. In other words, the groove 231 is a portion recessed from a lower surface of the conductor 23. Alternatively, the groove 231 is a portion obtained by removing a part of the conductor 23. For example, as illustrated in FIG. 4, the groove 231 has a triangular shape in a cross section in the X direction and the Z direction (or along an XZ plane). Note that, the groove 231 also has a structure including a plurality of irregularities on the lower surface of the conductor 23. The groove 231 also has a structure including a plurality of recesses or a plurality of protrusions on the lower surface of the conductor 23.

As illustrated in FIG. 2, a length in the Y direction of the groove 231 is set to be equal to or shorter than a length in the Y direction of the portion 23b of the conductor 23.

The groove 231 is arranged in the linear portion 23bs of the portion 23b in the conductor 23. The groove 231 is arranged, for example, within a range from a beginning of the linear portion 23bs (or an end of the curved portion 23ab) to an intermediate point between the beginning and the end of the linear portion 23bs. As illustrated in FIG. 4, a length from the beginning to the end of the linear portion 23bs is set to L, and half the length is set to (L/2). Then, the groove 231 is arranged within a range of the length (L/2) from the beginning of the linear portion 23bs.

The connector 32 is provided between the source electrode 10s of the semiconductor chip 10 and the portion 23a of the conductor 23. A boundary between the recessed portion of the groove 231 and the lower surface of the portion 23a (or an end of the groove 231) is in contact with the connector 32.

### 1.3 Configuration of First Modification

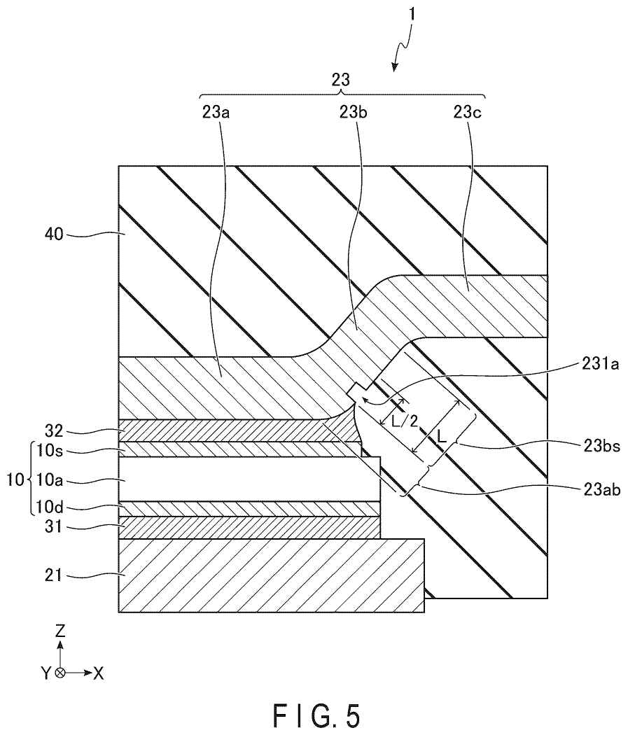

A semiconductor device 1 according to a first modification of the first embodiment will be next described. FIG. 5 is an enlarged view of a portion A as in FIG. 4, and is a cross-sectional view illustrating a connection structure between the source electrode 10s of the semiconductor chip 10 and the conductor 23. Here, description of the drawing corresponding to FIG. 3 is omitted.

In the first modification, a cross-sectional shape is different from that of a groove 231 in the first embodiment. As illustrated in FIG. 5, a groove 231a has a quadrangular shape in a cross section in the X direction and the Z direction. Other configurations are similar to those of the first embodiment.

### 1.4 Configuration of Second Modification

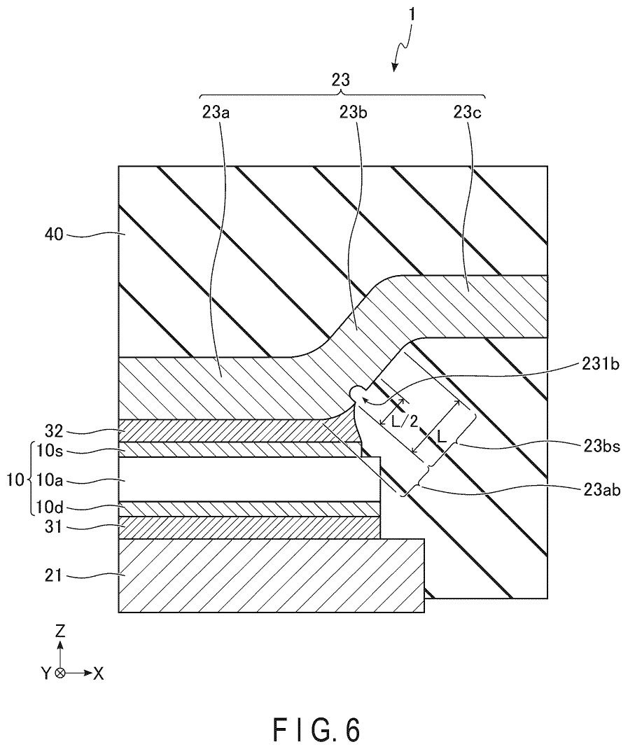

A semiconductor device 1 according to a second modification of the first embodiment will be next described. FIG. 6 is an enlarged view of a portion A as in FIG. 4, and is a cross-sectional view illustrating a connection structure between the source electrode 10s of the semiconductor chip 10 and a conductor 23. Herein also, description of the drawing corresponding to FIG. 3 is omitted.

In the second modification, a cross-sectional shape is different from that of a groove 231 in the first embodiment as in the first modification. As illustrated in FIG. 6, a groove 231b has a semicircular shape or a shape obtained by cutting an ellipse (or an oval) along a minor axis in a cross section in the X direction and the Z direction. Other configurations are similar to those of the first embodiment.

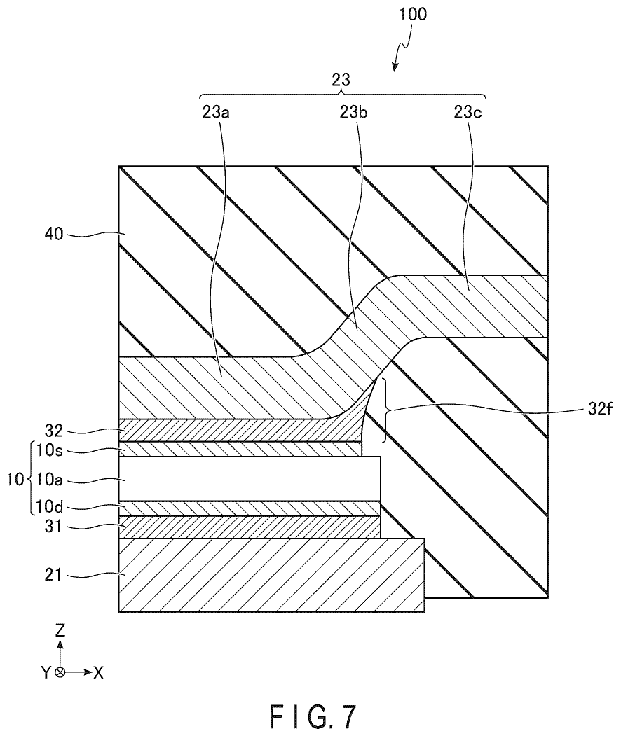

Hereinafter, a defect in a semiconductor device 100 according to a comparative example will be described with reference to FIG. 7, and an effect of the present embodiment will be described thereafter. FIG. 7 is an enlarged cross-sectional view illustrating a connection structure between a semiconductor chip 10 and a conductor 23 in the semiconductor device 100 according to the comparative example.

In the semiconductor device 100 according to the comparative example, a groove is not provided on a first surface of a portion 23b in the conductor 23. In such a structure, as illustrated in FIG. 7, a connector 32 crawls up from an end of a region where the semiconductor chip 10 and a portion 23a are connected to each other to the portion 23b to form a large fillet 32f of the connector 32 in some cases. When such fillet 32f is formed, a cavity in which the connector 32 does not exist is formed between the semiconductor chip 10 and the conductor 23 due to an insufficient amount of the connector 32 in some cases. In this case, a connection area between the semiconductor chip 10 and the conductor 23 becomes insufficient, and a resistance value between the semiconductor chip 10 and the conductor 23 increases. Furthermore, a current supply amount to the semiconductor chip 10 decreases, and a defect that performance of the semiconductor chip 10 cannot be sufficiently exhibited occurs.

If there is the cavity between the semiconductor chip 10 and the conductor 23, when a resin 40 is formed, a part of resin of the resin enters the cavity in some cases.

When the resin enters the cavity, there is a possibility that thermal stress to a distal end of the semiconductor chip 10 and the conductor 23 into which the resin has entered increases due to a change in temperature caused by an external environment or thermal stress such as heat generated in the semiconductor device. Due to this increase in thermal stress, there is a possibility that peeling occurs at an interface between the semiconductor chip 10 and the connector 32 and an interface between the conductor 23 and the connector 32, and reliability of the semiconductor device 1 is deteriorated.

In the first embodiment and the first and second modifications, the groove 231 is provided on the first surface of the portion 23b of the conductor 23, that is, on the same surface as the surface on which the connector (for example, solder) 32 is provided.

By providing the groove 231 in the portion 23b of the conductor 23, for example, it is possible to prevent the connector 32 from crawling up or wetting up to the portion 23b due to surface tension acting on the end (or an edge) of the groove 231. Therefore, a crawling up amount of the connector 32 to the portion 23b can be limited, and a size of the fillet formed on the end of the portion 23a can be controlled.

Furthermore, by preventing the connector 32 from crawling up to the portion 23b, it is possible to reduce formation of the cavity between the semiconductor chip 10 and the conductor 23. Therefore, the connection area between the semiconductor chip 10 and the conductor 23 can be sufficiently secured, and it is possible to prevent the resistance value between the semiconductor chip 10 and the conductor 23 from increasing. Furthermore, the current supply amount to the semiconductor chip 10 can be prevented from decreasing, and the performance of the semiconductor chip 10 can be sufficiently exhibited.

Since the formation of the cavity can be reduced, it is possible to reduce the entry of the resin into the cavity, and it is possible to suppress the thermal stress applied to the distal end of the semiconductor chip 10 and the conductor 23. Therefore, it is possible to prevent peeling occurring at the interfaces between the semiconductor chip 10 and the connector 32 and between the conductor 23 and the connector 32, and to improve reliability of the semiconductor device 1.

By preventing the connector 32 from crawling up to the portion 23b, it is possible to suppress positional displacement of the semiconductor chip 10 and the conductor 23 at the time of joining of the semiconductor chip 10 and the conductor 23.

As described above, according to the semiconductor device 1 of the first embodiment, the performance and reliability can be improved.

### 2. Second Embodiment

A semiconductor device according to a second embodiment will be next described. In the second embodiment, a roughened portion obtained by applying roughening treatment to a linear portion 23bs of a portion 23b in a conductor 23 is provided. In the second embodiment, a point different from that in the first embodiment is mainly described. Other configurations not described are similar to those of the first embodiment.

### 2.1 Configuration of Semiconductor Device

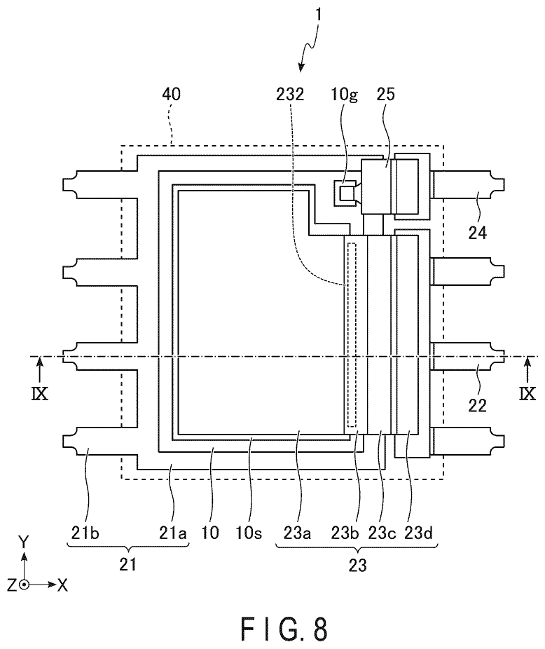

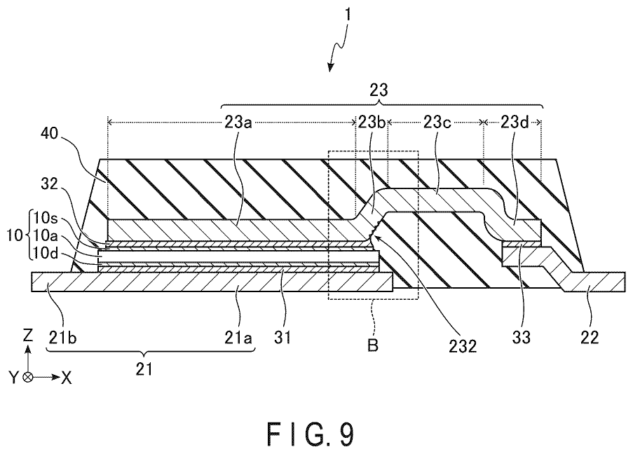

A configuration of a semiconductor device 1 according to the second embodiment is described with reference to FIGS. 8 and 9. FIG. 8 is a plan view illustrating a configuration of the semiconductor device according to the second embodiment. FIG. 9 is a cross-sectional view of the semiconductor device taken along line IX-IX in FIG. 8. FIG. 8 is a diagram as seen through a resin 40 covering the semiconductor device 1.

As illustrated in FIGS. 8 and 9, a roughened portion 232 is provided on a first surface of the portion 23b in the conductor 23. The roughened portion 232 will be described later in detail.

### 2.2 Configuration of Roughened Portion of Conductor

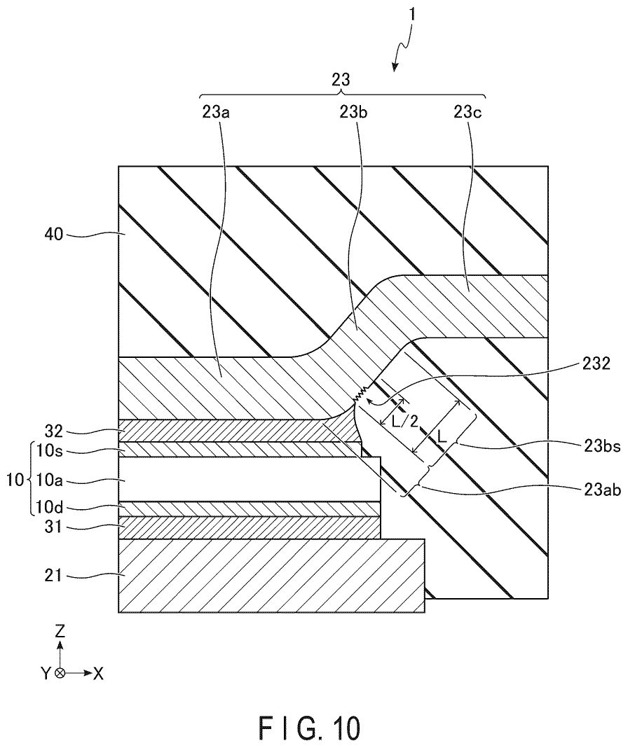

Next, a connection structure between the semiconductor chip 10 and the conductor 23 and the roughened portion 232 provided in the portion 23b of the conductor 23 will be described in detail with reference to FIG. 10. FIG. 10 is an enlarged view of a portion B in FIG. 9, and is a cross-sectional view illustrating the connection structure between the source electrode 10s of the semiconductor chip 10 and the conductor 23.

As illustrated in FIG. 10, the roughened portion 232 is provided on the first surface of the portion 23b of the conductor 23, that is, on a surface in an X direction (or in a −Z direction) of the portion 23b. In other words, the roughened portion 232 is provided on the surface of the conductor 23 continuous from a surface on which the connector 32 is provided.

The roughened portion 232 is a region obtained by applying the roughening treatment (or roughening processing) to the first surface of the portion 23b in the conductor 23. The roughened portion 232 includes a rough surface and a plurality of irregularities. Surface roughness of the roughened portion 232 has a surface area ratio (S-ratio) of 1.1 or more. That is, a surface area of a unit region of the roughened portion 232 is 1.1 or more times as large as a surface area of a unit region of the portion 23b to which the roughening treatment is not applied. Note that, the roughened portion 232 can also be regarded as a groove in terms of including a recess.

The roughened portion 232 is arranged in the linear portion 23bs of the portion 23b in the conductor 23. The roughened portion 232 is arranged, for example, within a range from a beginning of the linear portion 23bs (or an end of a curved portion 23ab) to an intermediate point between the beginning and the end of the linear portion 23bs. That is, as illustrated in FIG. 10, the roughened portion 232 is arranged within a range of a length L/2 from the beginning of the linear portion 23bs.

As illustrated in FIG. 8, a length in a Y direction of the roughened portion 232 is set to be equal to or shorter than a length in the Y direction of the portion 23b of the conductor 23.

The connector 32 is provided between the source electrode 10s of the semiconductor chip 10 and a portion 23a of the conductor 23. An end of the roughened portion 232 is in contact with the connector 32.

The roughened portion 232 is formed by applying the roughening treatment to the first surface of the portion 23b. Examples of the roughening treatment include a method of etching a surface with a chemical agent, a method of adding plating to the surface and the like.

As described above, in the second embodiment, the roughened portion 232 is arranged in the linear portion 23bs of the portion 23b in the conductor 23. Therefore, as in the first embodiment, a crawling up amount of the connector (for example, solder) 32 to the portion 23b can be limited, and a size of a fillet formed on the end of the portion 23a can be controlled. Other effects of the second embodiment are similar to those of the first embodiment.

### 3. Third Embodiment

A semiconductor device according to a third embodiment will be next described. In the third embodiment, a hole is provided in a linear portion 23bs of a portion 23b in a conductor 23. In the third embodiment, a point different from that in the first embodiment is mainly described. Other configurations not described are similar to those of the first embodiment.

### 3.1 Configuration of Semiconductor Device

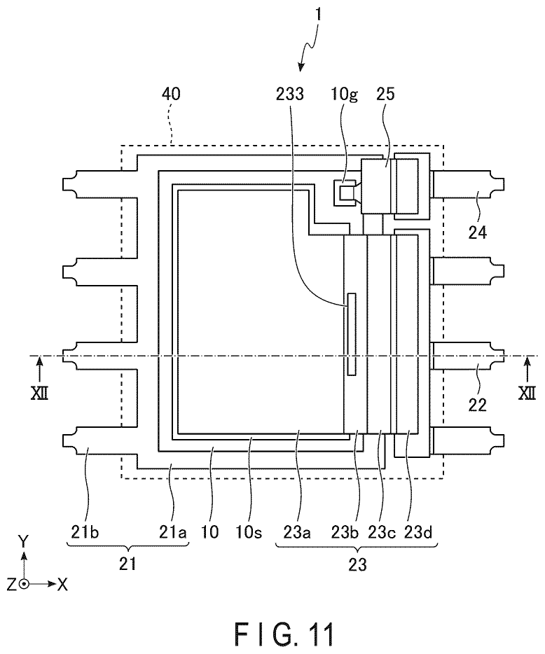

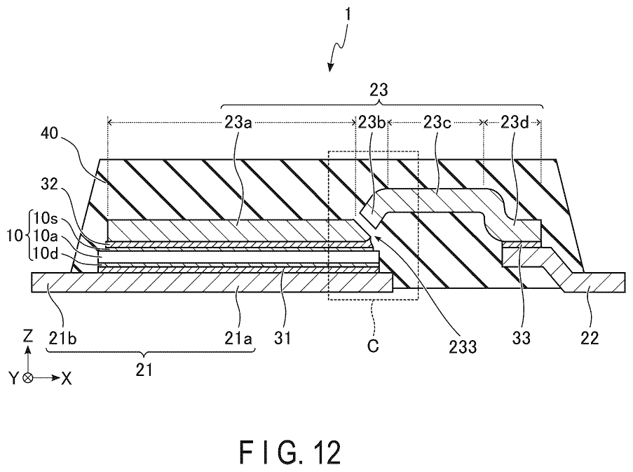

A configuration of a semiconductor device 1 according to the third embodiment is described with reference to FIGS. 11 and 12. FIG. 11 is a plan view illustrating a configuration of the semiconductor device according to the third embodiment. FIG. 12 is a cross-sectional view of the semiconductor device taken along line XII-XII in FIG. 11. FIG. 11 is a diagram as seen through a resin 40 covering the semiconductor device 1.

As illustrated in FIGS. 11 and 12, a hole 233 is provided in the portion 23b in the conductor 23. The hole 233 is a portion penetrating from a first surface to a second surface of the portion 23b in the conductor 23. The hole 233 will be described later in detail.

### 3.2 Configuration of Hole of Conductor

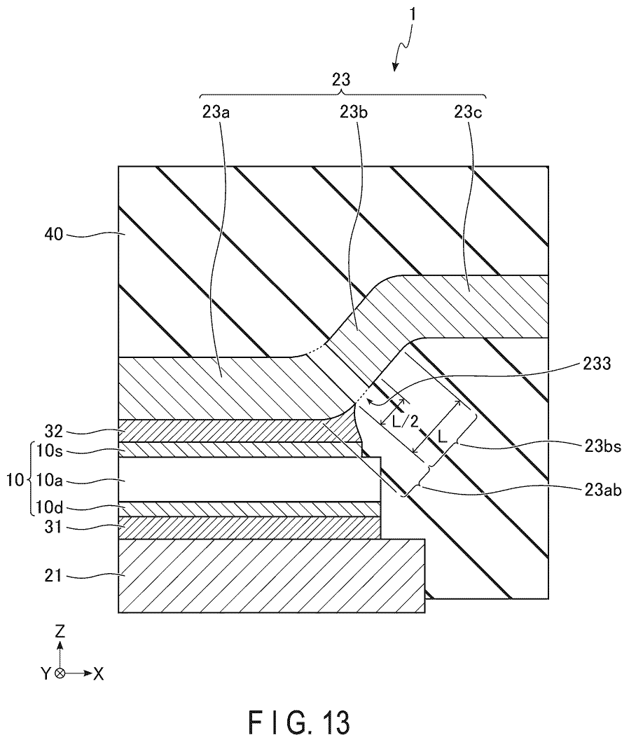

Next, a connection structure between the semiconductor chip 10 and the conductor 23, and the hole 233 provided in the portion 23b of the conductor 23 will be described in detail with reference to FIG. 13. FIG. 13 is an enlarged view of a portion C in FIG. 12, and is a cross-sectional view illustrating the connection structure between the source electrode 10s of the semiconductor chip 10 and the conductor 23.

As illustrated in FIG. 13, the hole 233 is provided in the portion 23b in the conductor 23. The hole 233 penetrates from the first surface to the second surface of the portion 23b in the conductor 23.

The hole 233 is arranged in the linear portion 23bs of the portion 23b in the conductor 23. The hole 233 is arranged, for example, within a range from a beginning of the linear portion 23bs (or an end of a curved portion 23ab) to an intermediate point between the beginning and the end of the linear portion 23bs. That is, as illustrated in FIG. 13, the hole 233 is arranged within a range of a length (L/2) from the beginning of the linear portion 23bs.

A planar shape of the hole 233 is a quadrangular shape. That is, as illustrated in FIG. 11, the hole 233 has a quadrangular shape in a plan view as seen in an X direction (or from above).

A length in the Y direction of the hole 233 is set within a range in which a resistance value (or ON resistance) in the conductor 23 does not cause a problem. For example, as illustrated in FIG. 11, the length in the Y direction of the hole 233 is set to be equal to or shorter than half a length in the Y direction of the portion 23b.

The connector 32 is provided between the source electrode 10s of the semiconductor chip 10 and a portion 23a of the conductor 23. An end of the hole 233 is in contact with the connector 32.

### 3.3 Configuration of First Modification

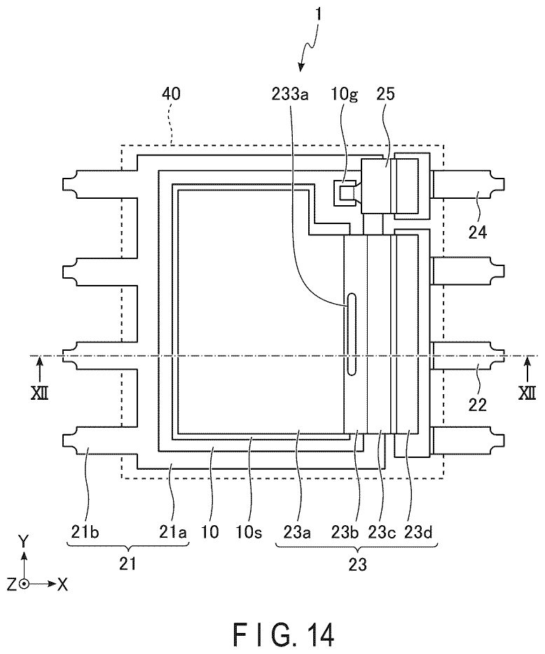

A semiconductor device 1 according to a first modification of the third embodiment will be next described. FIG. 14 is a plan view illustrating a configuration of the semiconductor device according to the first modification. FIG. 14 is a diagram as seen through a resin 40 covering the semiconductor device 1.

In the first modification, a planar shape is different from that of a hole 233 in the third embodiment. As illustrated in FIG. 14, a hole 233a has an elliptical shape (or an oval shape) in a plan view as seen in an X direction (or from above). Other configurations are similar to those of the third embodiment.

### 3.4 Configuration of Second Modification

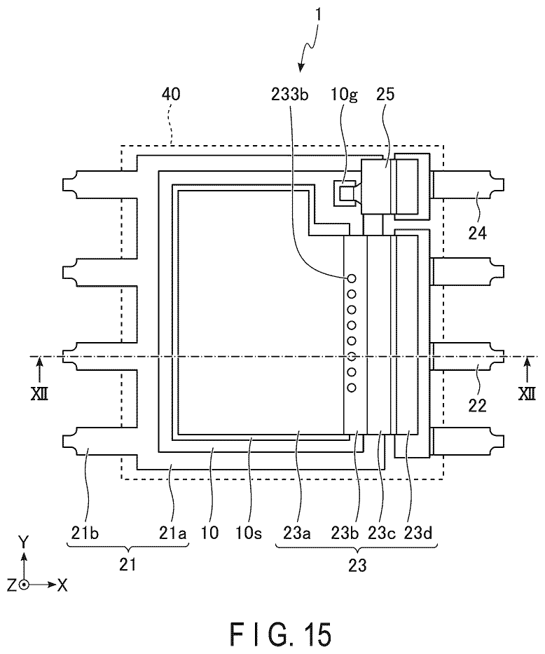

A semiconductor device 1 according to a second modification of the third embodiment will be next described. FIG. 15 is a plan view illustrating a configuration of the semiconductor device according to the second modification. FIG. 15 is a diagram as seen through a resin 40 covering the semiconductor device 1.

In the second modification, a planar shape is different from that of a hole 233 in the third embodiment as in the first modification. As illustrated in FIG. 15, a plurality of holes 233b is arrayed in a Y direction in a plan view as seen in an X direction (or from above). Each of the holes 233b has a circular shape. Note that, the shape of each of the holes 233b is not limited to the circular shape, and may be other shapes such as a quadrangular shape and a triangular shape. Other configurations are similar to those of the third embodiment.

As described above, in the third embodiment and the first and second modifications, the hole 233 (or 233a, 233b) is provided in the linear portion 23bs of the portion 23b in the conductor 23. Therefore, as in the first embodiment, a crawling up amount of the connector (for example, solder) 32 to the portion 23b can be limited, and a size of a fillet formed on the end of the portion 23a can be controlled.

In the configuration of the third embodiment and the first and second modifications, at a forming step of the resin 40, a part of the resin 40 enters the hole 233 (or 233a, 233b). As the part of the resin 40 enters the hole 233 of the conductor 23, adhesion between the conductor 23 and the resin 40 is enhanced. Therefore, occurrence of peeling between the conductor 23 and the resin 40 can be reduced, and reliability of the semiconductor device 1 can be improved. Other effects of the third embodiment and the first and second modifications are similar to those of the first embodiment.

### 4. Fourth Embodiment

A semiconductor device according to a fourth embodiment will be next described. In the first embodiment described above, a conductor 23 and a conductor 22 separate from each other are connected by a connector 33, but in the fourth embodiment, the conductor 23 and the conductor 22 have an integrally molded structure. In the fourth embodiment, a point different from that in the first embodiment is mainly described. Other configurations not described are similar to those of the first embodiment.

### 4.1 Configuration of Semiconductor Device

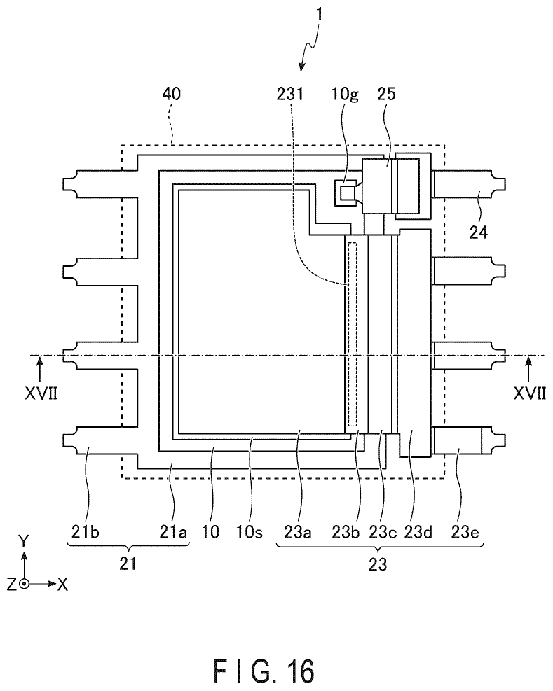

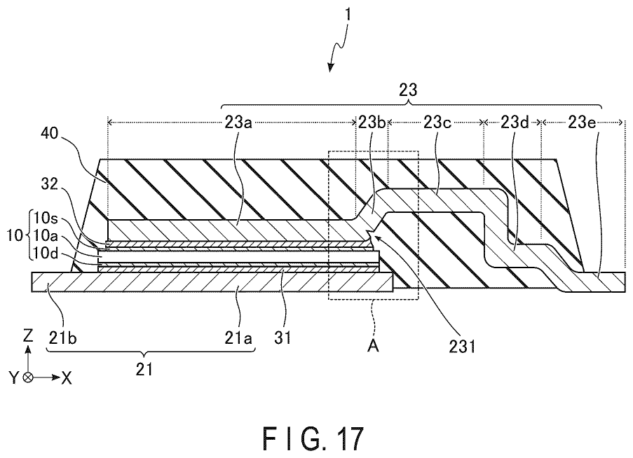

A configuration of a semiconductor device 1 according to the fourth embodiment is described with reference to FIGS. 16 and 17. FIG. 16 is a plan view illustrating a configuration of the semiconductor device according to the fourth embodiment. FIG. 17 is a cross-sectional view of the semiconductor device taken along line XVII-XVII in FIG. 16. FIG. 16 is a diagram as seen through a resin 40 covering the semiconductor device 1.

As illustrated in FIGS. 16 and 17, the conductor 23 includes portions (or plates) 23a, 23b, 23c, and 23d, and further includes a portion (or a plate, a terminal) 23e.

The portion 23e is a portion corresponding to the conductor 22 in the first embodiment. The portion 23e is integrally molded with the portion 23d. The portion 23e is a region continuous from the portion 23d, extending from the portion 23d in a direction intersecting the X direction (for example, in an oblique direction with respect to the X direction), and further extending linearly in the X direction. The portion 23e functions as a lead terminal (for example, a source terminal) connectable to the outside.

### 4.2 Configuration of Groove of Conductor

As illustrated in FIGS. 16 and 17, a configuration of a groove 231 of the conductor 23 in the fourth embodiment is similar to that in the first embodiment.

### 4.3 Configuration of First Modification

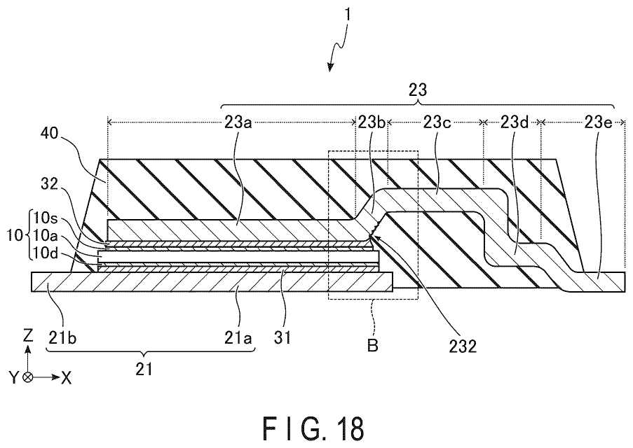

A semiconductor device 1 according to a first modification of the fourth embodiment will be next described. FIG. 18 is a cross-sectional view illustrating a configuration of the semiconductor device of the first modification.

In the first modification, a structure in which the conductor 23 and the conductor 22 are integrally molded is applied to the semiconductor device according to the second embodiment. As illustrated in FIG. 18, the conductor 23 includes portions (or plates) 23a, 23b, 23c, and 23d, and further includes a portion (or a plate, a terminal) 23e. The portion 23e is integrally molded with the portion 23d, and functions as a lead terminal (for example, a source terminal).

As illustrated in FIG. 18, a configuration of a roughened portion 232 of the conductor 23 in the first modification is similar to that in the second embodiment.

### 4.4 Configuration of Second Modification

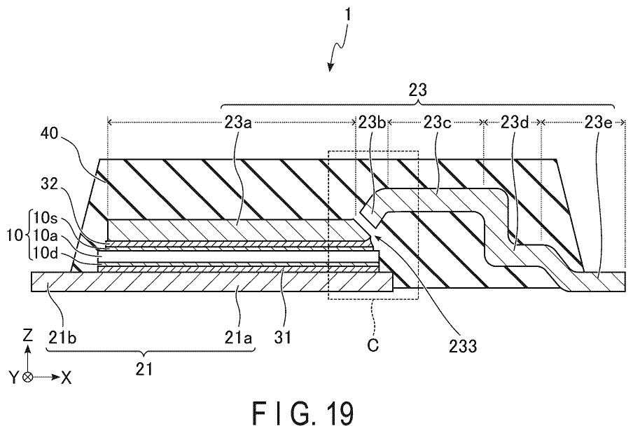

A semiconductor device 1 according to a second modification of the fourth embodiment will be next described. FIG. 19 is a cross-sectional view illustrating a configuration of the semiconductor device according to the second modification.

In the second modification, a structure in which the conductor 23 and the conductor 22 are integrally molded is applied to the semiconductor device according to the third embodiment. As illustrated in FIG. 19, the conductor 23 includes portions (or plates) 23a, 23b, 23c, and 23d, and further includes a portion (or a plate, a terminal) 23e as in the first modification. The portion 23e is integrally molded with the portion 23d, and functions as a lead terminal (for example, a source terminal).

As illustrated in FIG. 19 a configuration of a hole 233 of the conductor 23 in the second modification is similar to that in the third embodiment.

As described above, in the fourth embodiment and the first and second modifications, the conductor 23 and the conductor 22 included in the first, second, and third embodiments are integrally molded and provided as the conductor 23. Therefore, the configuration of the conductor connected to the source electrode 10s and functioning as the lead terminal can be simplified. Other effects of the fourth embodiment and the first and second modifications are similar to those of the first, second, and third embodiments.

Note that, in the first to third embodiments described above, the example in which the semiconductor device forms the MOS field effect transistor (that is, MOSFET) has been described, but the semiconductor device may form another switching element, for example, an insulated gate bipolar transistor (IGBT). In a case where the semiconductor device forms the IGBT, a source corresponds to an emitter, and a drain corresponds to a collector.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first conductor;
a second conductor;
a semiconductor chip provided between the first conductor and the second conductor; and
a first connector provided between the semiconductor chip and the second conductor,
wherein the second conductor includes a first plate, a second plate, and a third plate, which are continuously provided,
the first plate extends in a first direction along a main surface of the semiconductor chip and is connected to the semiconductor chip via the first connector,
the second plate extends from the first plate in a direction intersecting the first direction, and includes a first surface continuous from a surface on which the first connector is provided, and includes a groove provided on the first surface, and
the third plate extends from the second plate in the first direction.

2. The semiconductor device according to claim 1,
wherein the groove is a portion recessed from the first surface of the second plate.

3. The semiconductor device according to claim 2,
wherein a boundary between the recessed portion of the groove and the first surface is in contact with the first connector.

4. The semiconductor device according to claim 1,
wherein the direction in which the second plate extends is an oblique direction with respect to the first direction.

5. The semiconductor device according to claim 1,
wherein the first surface in the second plate of the second conductor extends linearly.

6. The semiconductor device according to claim 5,
wherein the groove is arranged between a beginning of the first surface in the second plate to an intermediate position between the beginning and an end of the first surface.

7. The semiconductor device according to claim 5,
wherein the second conductor includes a curved portion provided in a curved shape between the first plate and the second plate, and
the groove is arranged between an end of the curved portion to an intermediate position between the beginning and an end of the first surface.

8. The semiconductor device according to claim 1,
wherein the groove includes a surface including a plurality of irregularities.

9. The semiconductor device according to claim 1, further comprising:
a third conductor provided separately from the first conductor; and
a second connector,
wherein the second conductor includes a fourth plate,
the fourth plate extends from the third plate in a second direction intersecting the first direction, and further extends in the first direction, and
the second connector is provided between the third conductor and the fourth plate.

10. The semiconductor device according to claim 1,
wherein the groove includes a surface including a plurality of recesses.

11. The semiconductor device according to claim 1,
wherein the second conductor includes a fourth plate and a terminal,
the fourth plate extends from the third plate in a second direction intersecting the first direction, and further extends in the first direction, and
the terminal extends from the fourth plate in a direction intersecting the first direction, and further extends in the first direction.

12. A semiconductor device comprising:
a first conductor;
a second conductor;
a semiconductor chip provided between the first conductor and the second conductor; and
a first connector provided between the semiconductor chip and the second conductor,
wherein the second conductor includes a first plate, a second plate, and a third plate, which are continuously provided,
the first plate extends in a first direction along a main surface of the semiconductor chip and is connected to the semiconductor chip via the first connector,
the second plate extends from the first plate in a direction intersecting the first direction, and includes a hole, and
the third plate extends from the second plate in the first direction.

13. The semiconductor device according to claim 12,
wherein the second plate includes a first surface and a second surface on a side opposite to the first surface, and
the hole penetrates from the first surface to the second surface.

14. The semiconductor device according to claim 12,
wherein an end of the hole is in contact with the first connector.

15. The semiconductor device according to claim 12,
wherein the direction in which the second plate extends is an oblique direction with respect to the first direction.

16. The semiconductor device according to claim 12,
wherein the second plate of the second conductor includes a linear portion that extends linearly, and
the hole is arranged in the linear portion.

17. The semiconductor device according to claim 16,
wherein the hole is arranged between a beginning of the linear portion and an intermediate position between the beginning and an end of the linear portion.

18. The semiconductor device according to claim 16,
wherein the second conductor includes a curved portion provided in a curved shape between the first plate and the second plate, and
the hole is arranged between an end of the curved portion to an intermediate position between the beginning and an end of the linear portion.

19. The semiconductor device according to claim 12, further comprising:
a third conductor provided separately from the first conductor; and
a second connector,
wherein the second conductor includes a fourth plate,
the fourth plate extends from the third plate in a second direction intersecting the first direction, and further extends in the first direction, and
the second connector is provided between the third conductor and the fourth plate.

20. The semiconductor device according to claim 12, further comprising:
a resin that covers the semiconductor chip and the second conductor,
wherein a part of the resin enters the hole of the second conductor.
